(19) United States
(12) Patent Application Publication
(10) Pub. No.: US 2026/0019048 A1
(43) Pub. Date: Jan. 15, 2026

(54) ONE WIRE SERIAL INTERFACE FOR AMPLIFIERS

(71) Applicant: Skyworks Solutions, Inc., Irvine, CA (US)

(72) Inventors: Thomas Obkircher, Santa Ana, CA (US); Peihua Ye, Irvine, CA (US)

(21) Appl. No.: 19/264,965

(22) Filed: Jul. 10, 2025

Related U.S. Application Data
(60) Provisional application No. 63/669,776, filed on Jul. 11, 2024.

(51) Int. Cl. H03F 3/19; H03F 1/52

(52) U.S. Cl. CPC H03F 3/19; H03F 1/52; H03F 2200/294; H03F 2200/451

(57) ABSTRACT

A front end module is presented, the FEM including a first input; a second input; an output; a low noise amplifier coupled to the first input, second input, and the output, the low noise amplifier including an analog core configured to receive an enable signal from the first input, the analog core further configured to detect edges, including rising edges and falling edges, of the enable signal and execute one or more operations based on the edges.

### CROSS-REFERENCE TO RELATED APPLICATIONS

This application claims priority under 35 U.S.C. § 119 (e) to U.S. Provisional Patent Application No. 63/669,776, titled ONE WIRE SERIAL INTERFACE FOR AMPLIFIERS, filed on Jul. 11, 2024, which is hereby incorporated by reference in its entirety for all purposes.

### BACKGROUND

### 1. Field of the Disclosure

At least one example in accordance with the present disclosure relates generally to control systems for front-end modules (FEMs).

### 2. Discussion of Related Art

Front-end modules are used in telecommunications to transmit and receive communication signals. Front-end modules may include transmitters and receivers, as well as associated circuitry, such as filters, amplifiers, and so forth.

### SUMMARY

According to at least one aspect of the present disclosure a front end module is presented, comprising: a first input; a second input; an output; a low noise amplifier coupled to the first input, second input, and the output, the low noise amplifier including an analog core configured to receive an enable signal from the first input, the analog core further configured to detect edges, including rising edges and falling edges, of the enable signal and execute one or more operations based on the edges.

In some examples, the analog core is configured to count a number of rising edges of the enable signal and execute an operation based on the number. In some examples, the operation includes at least one of checking the status of a fuse, blowing the fuse, or emulating blowing the fuse. In some examples, the analog core is configured to set the number to zero upon detecting a falling edge of the enable signal. In some examples, the FEM further comprises a delay circuit configured to provide a delay signal with a phase offset compared to the enable signal. In some examples, the count of the number of rising edges of the enable signal is increased when the delay signal is low and a rising edge of the enable signal is occurring. In some examples, the count of the number of rising edges of the enable signal is increased when the delay signal is high and a rising edge of the enable signal is occurring. In some examples, the analog core is configured to set the number to zero upon detecting a falling edge of the enable signal provided the delay signal is low. In some example, the analog core is configured to set the number to zero upon detecting a falling edge of the enable signal provided the delay signal is high. In some examples, the analog core is configured to count a number of falling edges of the enable and execute an operation based on the number. In some examples, the operation includes checking the status of a fuse, blowing the fuse, or emulating blowing the fuse. In some examples, the analog core is configured to set the number to zero upon detecting a rising edge of the enable signal. In some examples, the FEM further comprises a delay circuit configured to provide a delay signal with a phase offset compared to the enable signal. In some examples, the count of the number of falling edges of the enable signal is increased when the delay signal is low and a falling edge of the enable signal is occurring. In some examples, the count of the number of falling edges of the enable signal is increased when the delay signal is high and a falling edge of the enable signal is occurring. In some examples, the analog core is configured to set the number to zero upon detecting a rising edge of the enable signal provided the delay signal is low. In some examples, the analog core is configured to set the number to zero upon detecting a rising edge of the enable signal provided the delay signal is high. In some examples, the analog core further includes a buffer coupled to the first input and configured to buffer the enable signal; an analog delay circuit configured to provide a delay signal having a phase shift compared to the enable signal; a controller coupled to the buffer and to the delay circuit and configured to receive the enable signal and the delay signal and to count a number of edges of the enable signal based on a state of the delay signal; a fuse core coupled to the controller and containing one or more fuses configured to be blown; a bias generator coupled to the fuse core and configured to provide a bias signal to an RF core of the low noise amplifier, wherein the RF core is configured to amplify an input signal provided from the second input and to output an amplified signal to the output, the amplified signal being based on the input signal and the bias signal; a first high voltage input configured to provide power to the front end module; and a second high voltage input configured to provide a fuse voltage adequate to one or more fuses of the one or more fuses. In some examples, the bias signal provided to the RF core determines a gain of the RF core. In some examples, each fuse of the one or more fuses is coupled to a respective resistor, such that when the respective fuse is unblown, the first high voltage input is coupled, via the respective resistor, to the bias generator, and such that when the respective fuse is blown, the respective resistor no longer couples the first high voltage input to the bias generator. In some examples, the bias signal depends upon a number of unblown fuses of the one or more fuses.

### BRIEF DESCRIPTION OF THE DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIG. 1 illustrates a global positioning system front-end module according to an example;

FIG. 2 illustrates a low noise amplifier according to an example;

FIG. 3 illustrates a timing diagram according to an example; and

FIG. 4 illustrates a timing diagram according to an example.

### DETAILED DESCRIPTION

Amplifier circuits, such as integrated circuits containing amplifiers, low noise amplifiers (LNAs), power amplifiers (PAS), amplifiers situated in front end modules (FEMs), and so forth, may have variable performance over process. That is, amplifiers may be produced in batches where the performance of the individual amplifiers within a given batch and/or across batches vary with respect to other amplifiers in the same batch and/or other batches. This may occur because the process for producing the amplifiers is a physical process that may vary from unit to unit due to physical conditions that are difficult or impossible to control. As a result, a first amplifier produced using a given process may have a given gain at a given current level, while a second amplifier produced using the same process may have a completely different gain at the same current level. In some examples, a process may produce units such that a majority of the units have performance characteristics falling within a given range (e.g., the first and second amplifier may both have gains within a range of gains for a given and/or all current levels), but the range may be too large for some applications.

Different types of amplifiers may also have different characteristics compared to other types of amplifiers. For example, LNAs may show large variations in current consumption and gain at relatively low current levels (e.g., levels below 5 mA, 2 mA, 0.5 mA, and so forth). As a result, in some cases, the process variations between some individual LNAs may be most prominent at low current levels. Other types of amplifiers may have respective different characteristics as well, for example, related to dispersion, output voltage stability, performance at different frequency ranges, slew rate, and so forth.

To account for process variations between amplifiers, the bias of the amplifier may be trimmed. In some examples presented herein, the bias is trimmed using one or more fuses. The fuses may, in some examples, be programmed through a serial digital interface, such as 3-wire MIPI, 2-wire I2C, or 4-wire SPI interfaces, and so forth. However, multi-wire interfaces (2-wire, 3-wire, and so forth) require additional space, materials, and hardware. Moreover, most amplifiers (e.g., LNAs) are not produced with serial digital control interfaces, which means that to control the fuses, it may be necessary to add probe pins to the amplifier as control pins (e.g., as GPIO pins), which requires the addition of significant die area and limits the ability to trim the amplifier during early evaluation. Furthermore, the methods described above may also limit or eliminate the ability to evaluate the shift in bias trimming due to potential change of the fuses and/or fuse bits during assembly.

In some examples disclosed herein, one approach may be to use pulse modulated programming (PMP) via a single-wire interface to program the fuses and/or adjust the bias of the amplifier. However, PMP approaches require more die-area and a more complex controller implementation, as well as two types of analog delay circuit.

According to aspects of the present disclosure, amplifiers may be controlled using a new one wire interface that leverages the already existing GPIO pin present on most amplifiers without adding new pins (e.g., probe pins) or complex internal controllers. The one wire interface disclosed herein uses a sequence of high speed, short pulses as a programming packet prior to enabling the amplifier. An internal controller counts the number of received pulses and decodes the programming packet based on the number of received pulses. The controller then executes an operation depending on the decoded programming packet. The controller may, for example, emulate fuse behavior, blow fuses, monitor fuses, and so forth.

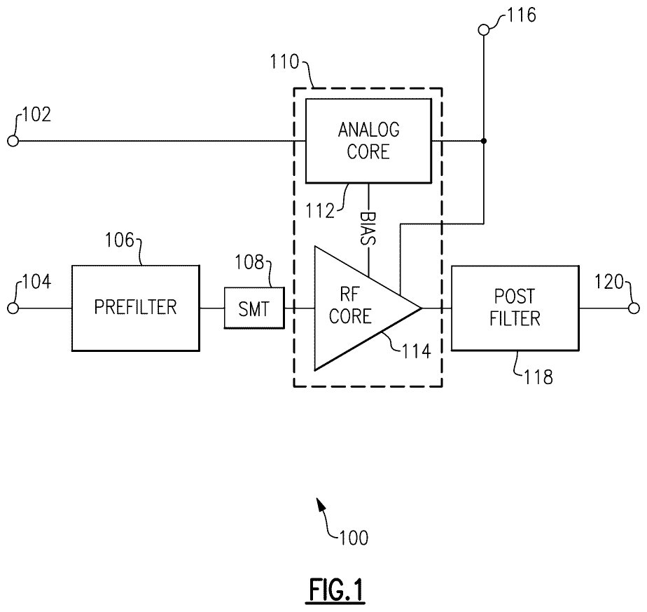

FIG. 1 illustrates a global positioning system (GPS) front-end module (FEM) 100 according to an example. The GPS FEM 100 includes an enable input 102 (“enable 102”), a radio frequency (RF) input 104, a prefilter 106, a matching inductor 108, a post filter 118, an RF output 120, a high voltage input 116, a low noise amplifier 110 (“LNA 110”), an analog core 112, and an RF core 114. The GPS FEM 100 is one example of a system configured to use an LNA (e.g., LNA 110) and to adjust the bias of said LNA using fuses, as described above.

The enable 102 is coupled to the LNA 110 via the analog core 112. The RF input 104 is coupled to the prefilter 106. The prefilter 106 is coupled to the matching inductor 108. The matching inductor 108 is coupled to the LNA 110 via the RF core 114 (e.g., via an input of the RF core 114). The analog core 112 is coupled to the RF core 114. The high voltage input 116 is coupled to the LNA 110 via the analog core 112 and the RF core 114. The post filter 118 is coupled to the LNA 110 via the RF core 114 (e.g., via an output of the RF core 114). The RF output 120 is coupled to the post filter 118.

The enable 102 is configured to receive an enable signal that may be used to turn the LNA 110 on and/or off, and/or which may be used to provide a sequence of pulses (e.g., high frequency pulses) to the LNA 110 and/or to the analog core 112.

The RF input 104 is configured to receive an RF signal and to provide the RF signal to the prefilter 106. The prefilter 106 is configured to filter the RF signal (e.g., to adjust one or more components of the RF signal, such as the frequency content, gain, phase, and so forth, of one or more components of the RF signal). The prefilter 106 may be further configured to provide the RF signal, after filtering, to the matching inductor 108. The matching inductor 108 may be configured to provide input matching (e.g., input impedance matching) for the LNA 110 and provides the RF signal to the LNA 110 (for example, to an input of the RF core 114).

The LNA 110 may be configured to amplify the RF signal received from the RF input 104 without significantly amplifying any unwanted frequency components (e.g., noise) present in the RF signal. The LNA 110 may then provide the amplified RF signal to the post filter 118. The post filter 118 may filter the amplified RF signal by adjusting one or more characteristics of one or more components of the amplified RF signal, and then provide the resulting signal to the RF output 120. For example, the post filter 118 may remove or attenuate unwanted frequency components of the amplified RF signal.

The high voltage input 116 provides a high voltage to the analog core 112 and/or to the RF core 114. The RF core 114 may be powered by the high voltage from the high voltage input 116, and the analog core 112 may be powered by the high voltage from the high voltage input 116.

The analog core 112 is configured to provide a bias current to the RF core 114 to adjust the bias of the LNA 110. That is, the RF core 114 may be the amplifier of the LNA 110, and the analog core 112 may be used to adjust the bias provided to the RF core 114. The RF core 114 may amplify the RF signal from the matching inductor 108 and provide the amplified RF signal to the post filter 118.

The analog core 112, RF core 114, and/or other components of the LNA 110 may contain one or more fuses configured to be controlled to adjust the bias of the RF core 114. The analog core 112 may contain further control circuitry.

In some examples, as mentioned above, the enable input 102 may provide a sequence of high frequency pulses to the analog core 112. Depending on that sequence of high frequency pulses, the analog core 112 may simulate the blowing of a given fuse, and/or may blow one or more of the fuses, and/or may monitor the state of one or more of the fuses and/or return an indication of the state of the one or more fuses to a user. In some examples, the analog core may also execute or control other analog or RF functions, such as LDO levels, Cascode voltages, tuning switches, and so forth. That is, in general, the sequence of high frequency pulses may contain any instruction, and the analog core 112 and/or other associated control circuitry may be configured to execute functions based on that instruction.

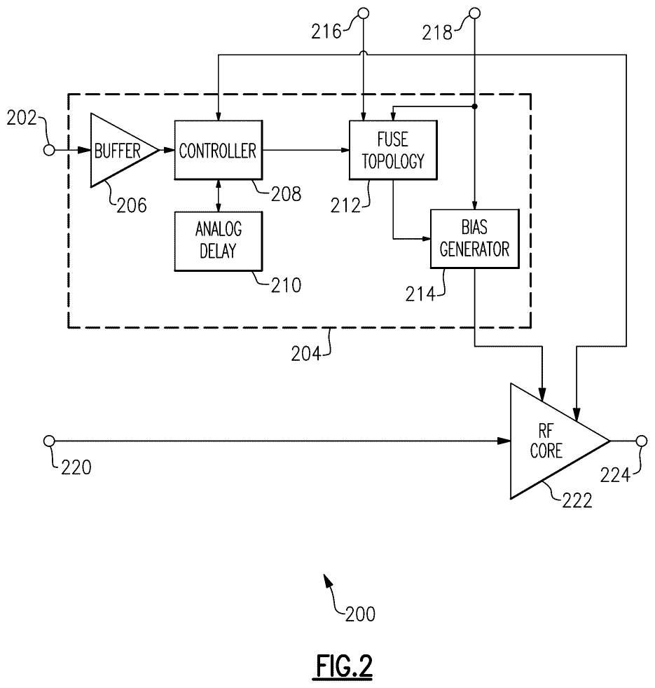

FIG. 2 illustrates an LNA 200 according to an example. The LNA 200 includes an enable input 202 (“enable 202”), an analog core 204, a first voltage input 216, a second voltage input 218, an RF input 220, an RF core 222, and an RF output 224. The analog core 204 includes a buffer 206, controller 208, analog delay 210, one or more fuses 212 (“fuse core 212”), and a bias generator 214.

The LNA 200 may use the single enable input 202 as an input to control the fuse core 212, thereby allowing different configurations of the fuse core 212 to be set and tested without the incorporation of additional probes, pins, and/or other hardware as would be required in the examples discussed prior to FIG. 1.

The enable 202 is coupled to an input of the buffer 206. The output of the buffer 206 is coupled to the controller 208. The controller 208 is coupled to the analog delay 210 and to the fuse core 212. The fuse core 212 is coupled to the bias generator 214. The first voltage input 216 is coupled to the fuse core 212. The second voltage input 218 is coupled to the fuse core 212, the bias generator 214, the RF core 222, and the controller 208. The bias generator 214 is coupled to the RF core 222. The RF input 220 is coupled to an input of the RF core 222, and the RF output 224 is coupled to an output of the RF core 222.

The enable 202 is configured to provide an LNA enable signal to the buffer 206, and may also be used to provide a sequence of high frequency pulses to the buffer 206. The buffer 206 buffers the signal from the enable 202 (e.g., the buffer may increase a current associated with the signal from the enable 202 while not changing the voltage of the signal). The buffer 206 may then provide the signal to the controller 208.

The controller 208 may decode the signal (as will be described below). Based on the decoded signal, the controller 208 may turn on the LNA 200 (e.g., so that the RF core 222 provides an output to the RF output 224) and/or adjust the mode of operation of the LNA 200 (e.g., by adjusting the configuration of the fuse core 212). In some examples, the controller 208 may perform other operations, such as other analog or RF functions, including controlling LDO levels, Cascode voltages, tuning switches, and so forth. In general, the controller 208 may be configured to execute any function desired, and the high frequency pulses (e.g., the decoded signal) may contain instructions pertaining to any of the functions for which the controller 208 is configured to control and/or execute.

The analog delay 210 may provide a delay signal to the controller 208. The delay signal may be a high frequency signal that corresponds to the high frequency sequence of pulses that may be provided at the enable 202. In some examples, the delay signal is based on and/or derived from the signal at the output of the buffer 206. The function of the analog delay 210 will be discussed in greater detail below.

The fuse core 212 contains one or more fuses that may be blown (e.g., opened) or emulated to be in a blown state (e.g., the fuse may behave as though it is open while not actually being opened). The fuse core 212 may provide an output to the bias generator 214 which alters the bias signal provided by the bias generator 214 to the RF core 222. In some examples, the output of the fuse core 212 may depend on which fuses are open (or being treated as open). That is, as fuses are blown, the parallel resistance of one or more resistors arranged in parallel to one another, and in series with respect to respective fuses corresponding to each resistor, may increase as resistors are no longer in parallel (due to the fuses being blown). This may reduce the current through the fuse core 212, which may increase current into the bias generator 214 via other routes (for example, via the connection between the bias generator 214 and the second voltage node 218). The change in the flow of current to the bias generator 214 may cause the bias signal generated by the bias generator 214 to change (e.g., to increase or decrease, depending on how the bias generator 214 is configured). Note that the bias generator 214 may also have its own set of bias resistors that may be selectively configured to determine the bias current provided by the bias generator 214.

The fuses of the fuse core 212 may also be associated with a specific resistance. For example, each fuse may have a different and/or predetermined resistance. The fuse core 212 may generate binary signals (signals having either a “high” or “low” state) based on the resistance and/or the state of the fuse.

The bias generator 214 generates the bias signal that is provided to the RF core 222 that may change or determine the bias point of the RF core 222. The RF core 222 receives an RF signal as an input, and outputs a signal based on the RF signal and the bias signal. The output of the RF core 222 may be a signal that has been adjusted (e.g., amplified).

The RF input 220 is configured to provide the RF signal to the RF core 222, the RF output 224 is configured to receive the output of the RF core 222.

The second voltage node 218 may provide a high voltage to the controller 208, fuse core 212, bias generator 214, and/or RF core 222. The high voltage may be used to power or drive any or all of the controller 208, fuse core 212, bias generator 214, and/or RF core 222.

The first voltage node 216 may be a special high voltage node that may provision a voltage sufficient (e.g., high enough) to blow (e.g., open) a fuse of the fuse core 212.

As mentioned above, the enable 202 may be used to provide control signals to the LNA 200. For example, an external source may provide a high frequency sequence of pulses as the control signal to the enable 202 which may then provide the sequence of pulses to the buffer 206. The controller 208 may receive the sequence of pulses (e.g., from the buffer 206) and may count or otherwise determine the number of pulses.

The controller 208 can decode the sequence of pulses based on the number of pulses to determine an operation to perform. For example, five pulses may correspond to emulating a given fuse or fuses in an open state, or monitoring the status of one or more fuses (e.g., determining whether a fuse is open or not), or opening (e.g., blowing) the fuse so that it can no longer be closed. Other commands may also be executed. Once the controller 208 has decoded the operation, the controller 208 may execute the operation to configure the fuse core 212 as instructed by the sequence.

In some examples, to determine when to stop counting the number of pulses in the sequence of pulses and/or to determine the number of pulses in the sequence of pulses, the controller 208 may use the delay signal from the analog delay 210 and the control signal from the enable 202.

In some examples, the analog delay 210 mirrors (e.g., is identical to) or approximately mirrors the enable signal, but with a phase shift of 180 degrees. The controller 208 may then increment the count of pulses if an edge (e.g., falling or rising) of the control signal corresponds to when the delay signal has a particular value (e.g., logic low or logic high). By way of illustration and example, suppose the controller 208 is configured to increment the count only on a falling edge of a pulse of the control signal, and to perform that incrementation only when the delay signal from the analog delay 210 is between a falling edge and a rising edge (e.g., in a low voltage state). If the controller 208 detects a falling edge of the control signal between a rising edge and a falling edge of the delay signal (e.g., during a logic high state), the controller 208 may determine that the count is over and may reset the count to zero and/or take any actions corresponding to the number of pulses counted. Conversely, if the controller 208 detects a falling edge of a pulse of the control signal while the delay signal is between a falling edge and a rising edge (e.g., during a low voltage state) the controller 208 may increment the count of the number of pulses by one.

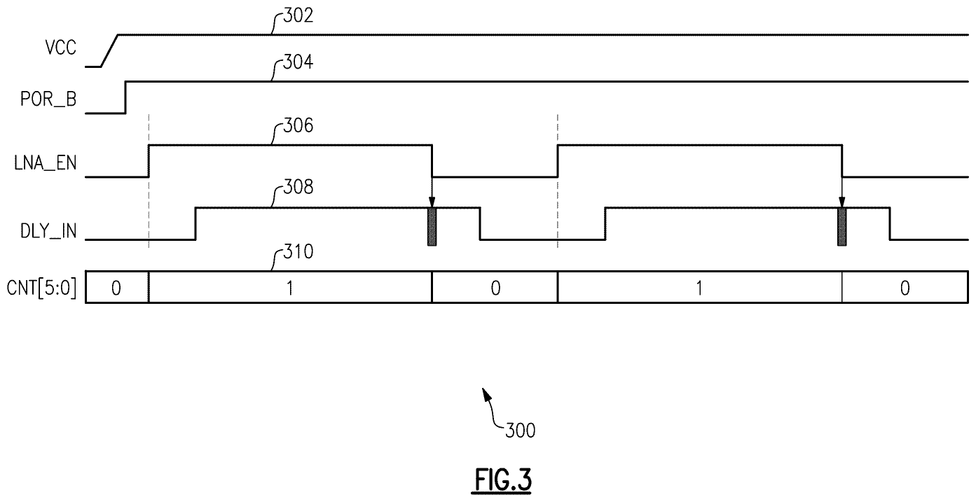

FIG. 3 illustrates a timing diagram 300 according to an example. The timing diagram 300 demonstrates how the controller 208 may, in some examples, determine the number of pulses. In particular, the timing diagram 300 illustrates a normal mode of operation where the enable signal (e.g., the control signal) is provided at a slow frequency rather than a high frequency.

The timing diagram 300 includes a VCC trace 302, an activity trace 304, an enable trace 306, a delay trace 308, and a count 310.

The VCC trace 302 indicates that a high voltage is available to the FEM, LNA, or other device when the VCC trace 302 is high. The VCC voltage corresponding to the VCC trace 302 may be the voltage used by the FEM or other device as the primary driving voltage (that is, other voltages in the FEM or other device) may be based on the VCC voltage, and the FEM or other device may lack power or lack sufficient power to operate as intended without the VCC voltage.

The enable trace 304 corresponds to the VCC trace 302 and indicates, when high, that the FEM or other device is able to access the VCC voltage for usages.

The enable trace 306 corresponds to the input and/or enable signal, for example, the enable signal at the LNA enable (enable input 202) of the LNA 200 and/or FEM 100 or other device. The enable trace 306 has a low state and a high state. In the example illustrated in the timing diagram 300, when the enable trace 306 goes from high to low states (e.g., on a falling edge) and the delay trace 308 is high, the count contained in the count 310 resets to zero. When the enable trace 306 goes from low to high and the delay trace 308 is low, the count contained in the count 310 increments by one.

The delay trace 308 is identical to the enable trace 306 but shifted in time (e.g., phase shifted) by some amount that may be determined by a delay circuit.

The count trace 310 contains a count of the number of pulses in the enable signal corresponding to the enable trace 306. The count increases and decreases as described above with respect to the enable trace 306.

In some examples, the delay signal is created by delaying the enable signal.

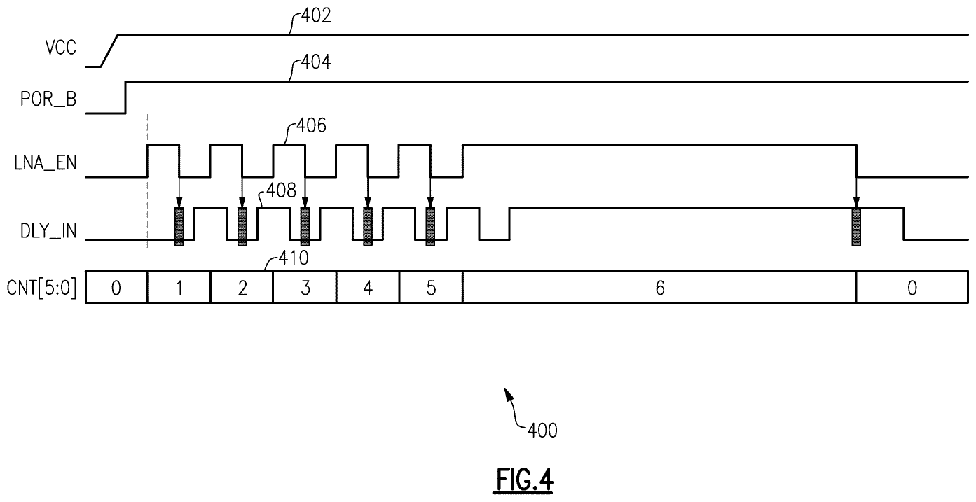

FIG. 4 illustrates a timing diagram 400 according to an example. The timing diagram illustrates how the controller 208 may determine the number of pulses when the enable signal is fluctuating at a high frequency.

FIG. 4 includes a VCC trace 402, an activity trace 404, an enable trace 406, a delay trace 408, and a count 410. The VCC trace 402 corresponds to the VCC trace 302 of FIG. 3. The activity trace 404 corresponds to the activity trace 304 of FIG. 3. The count 410 corresponds to the count 310 of FIG. 3. The enable trace 406 corresponds to the enable trace 306 of FIG. 3, and the delay trace 408 corresponds to the delay trace 308 of FIG. 3.

In contrast to FIG. 3, the enable trace 406 reflects an enable signal with a high frequency compared to that enable trace 306 in FIG. 3. The delay trace 408 mirrors the enable trace 406 but is shifted in time (e.g., has a phase shift compared to the enable trace 406). In the example illustrated in FIG. 4, the count 410 increases when the delay trace 408 is low and a rising edge of the enable trace 406 occurs. The count 410 resets when a falling edge of the enable trace 406 occurs while the delay trace 408 is high.

The total count may be translated into an instruction for the FEM and/or LNA, as described above. For example, four pulses may indicate a first function (such as checking the state of a first fuse), five pulses may indicate a second function (such as checking the state of a second fuse), and so forth. In general, for every fuse in a trimmable resistor array in the LNA or FEM, there may be a specific number of pulses which correspond to checking the state of a specific fuse, blowing a specific fuse, and/or emulating the blowing of a specific fuse.

In some examples, a minimum count is required for any operation. For example, counts one through four may not correspond to any operation (e.g., to account for random fluctuations in the enable signal that may occur during operation, turn on, or turn off of the system), and counts of five or more may correspond to an operation or instruction for the LNA, FEM, or other device.

Examples of the methods and systems discussed herein are not limited in application to the details of construction and the arrangement of components set forth in the description or illustrated in the accompanying drawings. The methods and systems are capable of implementation in other embodiments and of being practiced or of being carried out in various ways. Examples of specific implementations are provided herein for illustrative purposes only and are not intended to be limiting. In particular, acts, components, elements and features discussed in connection with any one or more examples are not intended to be excluded from a similar role in any other examples.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items.

References to “or” may be construed as inclusive so that any terms described using “or” may indicate any of a single, more than one, and all of the described terms. In addition, in the event of inconsistent usages of terms between this document and documents incorporated herein by reference, the term usage in the incorporated features is supplementary to that of this document; for irreconcilable differences, the term usage in this document controls.

Various controllers, such as the controller 208, may execute various operations discussed above. Using data stored in associated memory and/or storage, the controller 208 also executes one or more instructions stored on one or more non-transitory computer-readable media, which the controller 208 may include and/or be coupled to, that may result in manipulated data. In some examples, the controller 208 may include one or more processors or other types of controllers. In one example, the controller 208 is or includes at least one processor. In another example, the controller 208 performs at least a portion of the operations discussed above using an application-specific integrated circuit tailored to perform particular operations in addition to, or in lieu of, a general-purpose processor. As illustrated by these examples, examples in accordance with the present disclosure may perform the operations described herein using many specific combinations of hardware and software and the disclosure is not limited to any particular combination of hardware and software components. Examples of the disclosure may include a computer-program product configured to execute methods, processes, and/or operations discussed above. The computer-program product may be, or include, one or more controllers and/or processors configured to execute instructions to perform methods, processes, and/or operations discussed above.

Having thus described several aspects of at least one embodiment, it is to be appreciated various alterations, modifications, and improvements will readily occur to those skilled in the art. Such alterations, modifications, and improvements are intended to be part of, and within the spirit and scope of, this disclosure. Accordingly, the foregoing description and drawings are by way of example only.

What is claimed is:

1. A front end module comprising:
a first input;
a second input;
an output;
a low noise amplifier coupled to the first input, second input, and the output, the low noise amplifier including an analog core configured to receive an enable signal from the first input, the analog core further configured to detect edges, including rising edges and falling edges, of the enable signal and execute one or more operations based on the edges.

2. The front end module of claim 1 wherein the analog core is configured to count a number of rising edges of the enable signal and execute an operation based on the number.

3. The front end module of claim 2 wherein the operation includes at least one of checking the status of a fuse, blowing the fuse, or emulating blowing the fuse.

4. The front end module of claim 2 wherein the analog core is configured to set the number to zero upon detecting a falling edge of the enable signal.

5. The front end module of claim 4 further comprising a delay circuit configured to provide a delay signal with a phase offset compared to the enable signal.

6. The front end module of claim 5 wherein the count of the number of rising edges of the enable signal is increased when the delay signal is low and a rising edge of the enable signal is occurring.

7. The front end module of claim 5 wherein the count of the number of rising edges of the enable signal is increased when the delay signal is high and a rising edge of the enable signal is occurring.

8. The front end module of claim 5 wherein the analog core is configured to set the number to zero upon detecting a falling edge of the enable signal provided the delay signal is low.

9. The front end module of claim 5 wherein the analog core is configured to set the number to zero upon detecting a falling edge of the enable signal provided the delay signal is high.

10. The front end module of claim 1 wherein the analog core is configured to count a number of falling edges of the enable and execute an operation based on the number.

11. The front end module of claim 10 wherein the operation includes checking the status of a fuse, blowing the fuse, or emulating blowing the fuse.

12. The front end module of claim 10 wherein the analog core is configured to set the number to zero upon detecting a rising edge of the enable signal.

13. The front end module of claim 12 further comprising a delay circuit configured to provide a delay signal with a phase offset compared to the enable signal.

14. The front end module of claim 13 wherein the count of the number of falling edges of the enable signal is increased when the delay signal is low and a falling edge of the enable signal is occurring.

15. The front end module of claim 13 wherein the count of the number of falling edges of the enable signal is increased when the delay signal is high and a falling edge of the enable signal is occurring.

16. The front end module of claim 13 wherein the analog core is configured to set the number to zero upon detecting a rising edge of the enable signal provided the delay signal is low.

17. The front end module of claim 13 wherein the analog core is configured to set the number to zero upon detecting a rising edge of the enable signal provided the delay signal is high.

18. The front end module of claim 1 wherein the analog core further includes
a buffer coupled to the first input and configured to buffer the enable signal;
an analog delay circuit configured to provide a delay signal having a phase shift compared to the enable signal;
a controller coupled to the buffer and to the delay circuit and configured to receive the enable signal and the delay signal and to count a number of edges of the enable signal based on a state of the delay signal;
a fuse core coupled to the controller and containing one or more fuses configured to be blown;
a bias generator coupled to the fuse core and configured to provide a bias signal to an RF core of the low noise amplifier, wherein the RF core is configured to amplify an input signal provided from the second input and to output an amplified signal to the output, the amplified signal being based on the input signal and the bias signal;
a first high voltage input configured to provide power to the front end module; and
a second high voltage input configured to provide a fuse voltage adequate to one or more fuses of the one or more fuses.

19. The front end module of claim 18 wherein the bias signal provided to the RF core determines a gain of the RF core.

20. The front end module of claim 18 wherein each fuse of the one or more fuses is coupled to a respective resistor, such that when the respective fuse is unblown, the first high voltage input is coupled, via the respective resistor, to the bias generator, and such that when the respective fuse is blown, the respective resistor no longer couples the first high voltage input to the bias generator.
